(19) United States
(12) Patent Application Publication
(10) Pub. No.: US 2022/0196481 A1
(43) Pub. Date: Jun. 23, 2022

(54) INFRARED SENSOR AND INFRARED SENSOR DEVICE EQUIPPED WITH SAME

(71) Applicant: Panasonic Intellectual Property Management Co., Ltd., Osaka (JP)

(72) Inventors: Shoya KIDA, Shimane (JP); Nobuaki SHIMAMOTO, Fukui (JP); Nayuta MINAMI, Fukui (JP); Isao HATTORI, Fukui (JP); Naoki KOBAYASHI, Fukui (JP); Hiroshi YAMANAKA, Fukui (JP)

(21) Appl. No.: 17/598,862

(22) PCT Filed: Feb. 26, 2020
(86) PCT No.: PCT/JP2020/007564

§ 371 Date: Sep. 27, 2021

(30) Foreign Application Priority Data
Mar. 27, 2019 (JP) 2019-061929

(51) Int. Cl. G01J 5/16; G01J 5/02

(52) U.S. Cl. CPC G01J 5/16; G01J 2005/106; G01J 5/0205

(57) ABSTRACT

A film structural component is supported by a substrate. The film structural component includes a plurality of thermal infrared detectors arranged in an array. Each of the plurality of thermal infrared detectors includes a thermopile having a plurality of hot junctions and a plurality of cold junctions. An infrared sensor further includes a plurality of heaters and at least one thermometer. The plurality of heaters are provided on the first principal surface of the substrate. The at least one thermometer is provided on the first principal surface of the substrate and is configured to detect a temperature of the substrate. Each of the plurality of heaters faces another heater of the plurality of heaters via a region including the plurality of thermal infrared detectors in plan view in the thickness direction of the substrate.

### TECHNICAL FIELD

The present disclosure relates generally to infrared sensors and infrared sensor devices equipped with the infrared sensors and specifically to an infrared sensor including a substrate having a cavity and an infrared sensor device equipped with the infrared sensor.

### BACKGROUND ART

An infrared sensor device has been known which includes: an infrared sensor (an infrared sensor chip); an IC chip configured to perform signal processing of an output signal from the infrared sensor; and a package in which the infrared sensor and the IC chip are accommodated (Patent Literature 1).

The infrared sensor includes a plurality of pixel sections arranged in a two-dimensional array at the side of one surface of a semiconductor substrate. The pixel sections each have a thermal infrared detector and a MOS transistor which is a switching element for pixel selection. The thermal infrared detector has a temperature sensing unit including a plurality of (here, six) thermopiles connected in series to each other.

The infrared sensor has a hollow part (cavity) formed directly under part of each thermal infrared detector and at the side of the one surface of the semiconductor substrate. The thermal infrared detector includes a supporting part and a thin film structure section. The supporting part is in the vicinity of the hollow part at the side of the one surface of the semiconductor substrate. The thin film structure section covers the hollow part in plan view at the side of the one surface of the semiconductor substrate.

Each of the thermopiles has a plurality of hot junctions and a plurality of cold junctions. The plurality of hot junctions are in a first region of the thermal infrared detector, and the first region overlaps the hollow part. The plurality of cold junctions are in a second region of the thermal infrared detector, and the second region does not overlap the hollow part.

Note that the infrared sensor device further includes a thermistor configured to measure an absolute temperature and stored in the package.

In the infrared sensor and the infrared sensor device described in Patent Literature 1, temperatures of the cold junctions of each thermal infrared detector may vary.

### CITATION LIST

### Patent Literature

Patent Literature 1: JP 2012-8003 A

### SUMMARY OF INVENTION

An object of the present disclosure is to provide an infrared sensor including thermal infrared detectors each having cold junctions with reduced variations in temperature and an infrared sensor device including the infrared sensor.

An infrared sensor according to an aspect of the present disclosure includes a substrate and a film structural component. The substrate has a first principal surface and a second principal surface located on an opposite side of the first principal surface in a thickness direction of the substrate. The film structural component is supported by the substrate at a side of the first principal surface of the substrate. The film structural component includes a plurality of thermal infrared detectors arranged in an array. Each of the plurality of thermal infrared detectors includes a thermopile having a plurality of hot junctions and a plurality of cold junctions. The infrared sensor further includes a plurality of heaters and at least one thermometer. The plurality of heaters are provided on the first principal surface of the substrate. The at least one thermometer is provided on the first principal surface of the substrate and is configured to detect a temperature of the substrate. Each of the plurality of heaters faces another heater of the plurality of heaters via a region including the plurality of thermal infrared detectors in plan view in the thickness direction of the substrate.

An infrared sensor device according to an aspect of the present disclosure includes: the infrared sensor; and a signal processing device configured to perform signal processing of an output signal from the infrared sensor.

### BRIEF DESCRIPTION OF DRAWINGS

FIG. 1 is a layout diagram illustrating an infrared sensor according to a first embodiment;

FIG. 2 is a sectional view illustrating the infrared sensor along line A-A of FIG. 1;

FIG. 3 is a sectional view illustrating an infrared sensor device including the infrared sensor;

FIG. 4 is a layout diagram illustrating an infrared sensor according to a first variation of the first embodiment;

FIG. 5 is a layout diagram illustrating an infrared sensor according to a second variation of the first embodiment;

FIG. 6 is a layout diagram illustrating an infrared sensor according to a second embodiment;

FIG. 7 is a layout diagram illustrating an infrared sensor according to a third embodiment;

FIG. 8 is a layout diagram illustrating an infrared sensor according to a fourth embodiment;

### DESCRIPTION OF EMBODIMENTS

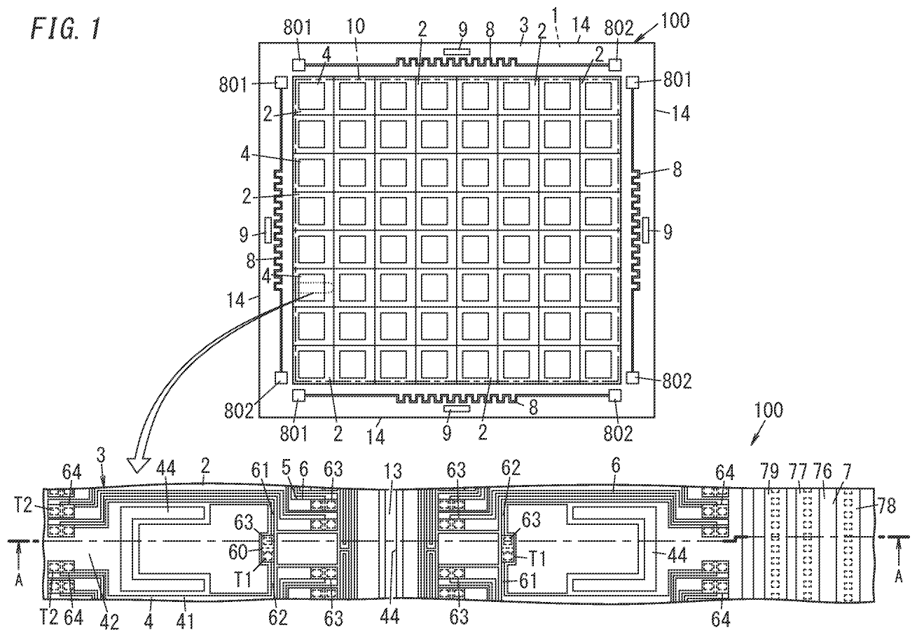

FIGS. 1 to 8 described in the following embodiments are schematic views, and the ratio of sizes and the ratio of thicknesses of components in the figures do not necessarily reflect actual dimensional ratios.

### First Embodiment

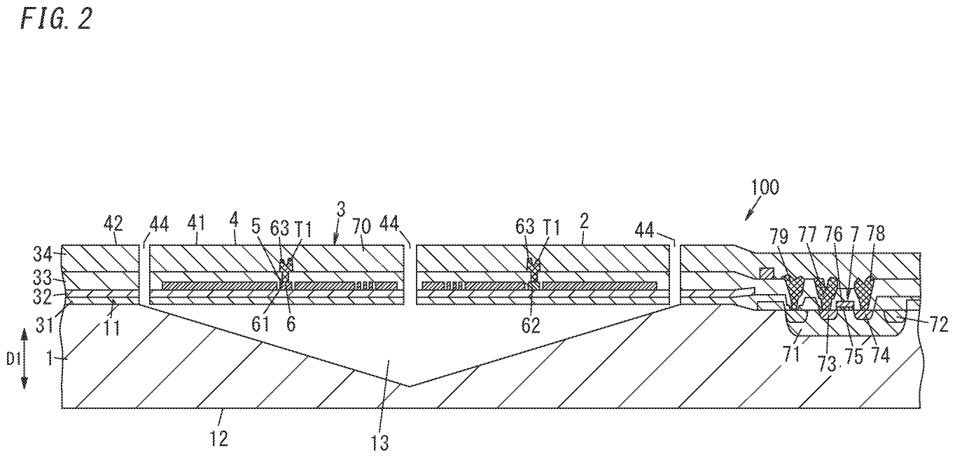

An infrared sensor 100 according to a first embodiment will be described below with reference to FIGS. 1 and 2.

The infrared sensor 100 includes a substrate 1 and a plurality of (e.g., 64) detectors (pixel sections) 2. The substrate 1 has a first principal surface 11 and a second principal surface 12. The detectors 2 are provided at the side of the first principal surface 11 of the substrate 1.

The second principal surface 12 is located on an opposite side from the first principal surface 11 in a thickness direction D1 (see FIG. 2) of the substrate 1. The outer peripheral shape of the infrared sensor 100 is, for example, a square shape in plan view in the thickness direction D1 of the substrate 1 of the infrared sensor 100. The outer peripheral shape of the infrared sensor 100 is not limited to the square shape but may be, for example, a rectangular shape.

The substrate 1 is a silicon substrate. The first principal surface 11 of the substrate 1 is a {100} plane. For example, the first principal surface 11 of the substrate 1 is a (100) plane. The first principal surface 11 of the substrate 1 may be, for example, a crystal surface having an off-angle greater than or equal to 0° and less than or equal to 5° from the {100} plane. As used herein, the “off-angle” is an inclined angle of the first principal surface 11 relative to the {100} plane. Thus, when the off-angle is 0°, the first principal surface 11 is the {100} plane.

The plurality of (e.g., 64) detectors 2 are arranged in an array at the side of the first principal surface 11 of the substrate 1. For example, the plurality of detectors 2 are arranged in a two-dimensional array of “m” rows and “n” columns (each of “m” and “n” is a natural number) at the side of the first principal surface 11 of one substrate 1. In the example shown in FIG. 1, “m” is 8, and “n” is 8, but this should not be construed as limiting. For example, “m” may be 16 and “n” may be 4.

The infrared sensor 100 includes a film structural component 3 which constitutes part of each of the plurality of detectors 2. The film structural component 3 is supported by the substrate 1 at the side of the first principal surface 11 of the substrate 1. In this embodiment, the film structural component 3 includes a plurality of thermal infrared detectors 4 corresponding to the plurality of detectors 2 on a one-to-one basis. That is, each of the plurality of thermal infrared detectors 4 is included in a corresponding detector 2 of the plurality of plurality of detectors 2. Thus, the plurality of thermal infrared detectors 4 are arranged in an array (in this embodiment, a two-dimensional array) at the side of the first principal surface 11 of the one substrate 1. More specifically, the plurality of thermal infrared detectors 4 are arranged in a two-dimensional array of eight rows and eight columns at the side of the first principal surface 11 of the one substrate 1.

The film structural component 3 includes a silicon oxide film 31, a silicon nitride film 32, an interlayer insulative film 33, and a passivation film 34. In the film structural component 3, the silicon oxide film 31, the silicon nitride film 32, the interlayer insulative film 33, and the passivation film 34 are aligned in this order from the side of the substrate 1. In this embodiment, the silicon oxide film 31 is directly supported by the substrate 1. The plurality of thermal infrared detectors 4 in the film structural component 3 include thermoelectric converters 5 formed on the silicon nitride film 32. The interlayer insulative film 33 covers the thermoelectric converters 5 at a surface side of the silicon nitride film 32. The interlayer insulative film 33 is, for example, a Boron Phosphorus Silicon Glass (BPSG) film. The passivation film 34 is, for example, a layered film of a Phospho-Silicate Glass (PSG) film and a Nondoped Silicate Glass (NSG) film formed on the PSG film. Note that in the film structural component 3, a layered film including the interlayer insulative film 33 and the passivation film 34 has portions which are provided in the thermal infrared detectors 4 and which serve also as an infrared ray absorbing film 70.

Each of the plurality of thermal infrared detectors 4 includes the thermoelectric converter 5. The thermoelectric converter 5 includes a plurality of (e.g., six) thermopiles 6. In the thermoelectric converter 5, the plurality of thermopiles 6 are connected in series to each other.

Each of the plurality of detectors 2 includes the thermal infrared detector 4 and a MOS transistor 7.

Each of the plurality of MOS transistors 7 is a switching element for pixel selection. In other words, each of the plurality of MOS transistors 7 is a switching element for extracting an output voltage from the thermoelectric converter 5. The silicon substrate constituting the substrate 1 is, for example, an n-type silicon substrate. Each of the plurality of MOS transistors 7 includes a well region 71 which is of p⁺-type, a drain region 73 which is of n+-type, a source region 74 which is of n⁺-type, a channel stopper region 72 which is of p⁺⁺-type, a gate insulative film 75, a gate electrode 76, a drain electrode 77, a source electrode 78, and an electrode 79 for grounding. The well region 71, the drain region 73, the source region 74, and the channel stopper region 72 are provided in the substrate 1. The gate insulative film 75 is provided on the first principal surface 11 of the substrate 1. The gate electrode 76 is provided on the gate insulative film 75. The drain electrode 77 is provided on the drain region 73. The source electrode 78 is provided on the source region 74. The electrode 79 for grounding is provided on the channel stopper region 72.

The infrared sensor 100 includes: a plurality of first wires (vertical read lines) to each of which first ends of the thermoelectric converters 5 of the plurality of (eight) detectors 2 in a corresponding one of the columns are commonly connected via the MOS transistors 7; and a plurality of second wires (horizontal signal lines) to each of which the gate electrodes 76 of the MOS transistors 7 of the plurality of (eight) detectors in a corresponding one of the rows are commonly connected. The infrared sensor 100 further includes: a plurality of third wires (ground lines) to each of which the well regions 71 of the MOS transistors 7 of the detectors 2 in a corresponding one of the columns are commonly connected; and a common ground line (a fourth wire) to which the ground lines are commonly connected. The infrared sensor 100 further includes a plurality of reference bias lines (fifth wires) to each of which second ends of the thermoelectric converters 5 of the plurality of detectors 2 in a corresponding one of the columns are commonly connected. In this embodiment, the gate electrodes 76 of the MOS transistors 7 are connected to a corresponding second wire of the plurality of second wires. Further, the source electrodes 78 of the MOS transistors 7 are connected to a corresponding fifth wires of the plurality of fifth wires via the thermoelectric converters 5. Furthermore, the drain electrodes 77 of the MOS transistors 7 are connected to a corresponding first wire of the plurality of first wires. Thus, the infrared sensor 100 enables output voltages of the plurality of detectors 2 to be sequentially read. The infrared sensor 100 includes: a plurality of (eight) first pads to which the plurality of first wires are connected on a one-to-one basis and which are used for outputting; a plurality of (eight) second pads to which the plurality of second wires are connected on a one-to-one basis; a third pad to which the plurality of third wires are commonly connected; and a fourth pad to which the fourth wire is commonly connected and which is used for reference biasing.

Moreover, the substrate 1 has a plurality of cavities 13 at the side of the first principal surface 11. The plurality of cavities 13 corresponds to the plurality of thermal infrared detectors 4 on a one-to-one basis. The opening shape of each cavity 13 in the first principal surface 11 of the substrate 1 is a rectangular shape. Each of the plurality of cavities 13 in the substrate 1 is provided directly under part of a corresponding thermal infrared detector 4 of the plurality of thermal infrared detectors 4. Thus, part of each of the plurality of thermal infrared detectors 4 is apart from the substrate 1 in the thickness direction D1 of the substrate 1. Each thermal infrared detector 4 has a portion which is located on an inner side of the opening edge of the cavity 13 in plan view in the thickness direction D1 of the substrate 1, and the portion has a plurality of slits 44 formed in the thickness direction D1 such that the slits 44 extend through the portion to be connected to (communicated with) the cavity 13. As described above, the substrate 1 of the infrared sensor 100 is the silicon substrate, and each cavity 13 in the substrate 1 has an inner side surface having four (111) planes intersecting each other. Each cavity 13 has, for example, a square pyramid shape.

The plurality of slits 44 formed in the plurality of thermal infrared detectors 4 divides portions of thermal infrared detectors 4 overlapping the cavities 13 in the thickness direction D1 of the substrate 1 into six regions, each of which includes one thermopile 6.

Each thermopile 6 has a plurality of (nine) thermocouples 60. Each of the plurality of thermocouples 60 includes an n-type polysilicon wire 61, a p-type polysilicon wire 62, and a first connector 63 via which a first end of the n-type polysilicon wire 61 and a first end of the p-type polysilicon wire 62 are electrically connected to each other. The n-type polysilicon wire 61 and the p-type polysilicon wire 62 are provided on the silicon nitride film 32. The material for the first connector 63 is, for example, an Al—Si alloy. Each thermopile 6 includes a second connector 64 via which a second end of the n-type polysilicon wire 61 and a second end of the p-type polysilicon wire 62 of adjacent thermocouples 60 of the plurality of thermocouples 60 are electrically connected to each other. The material for the second connector 64 is, for example, an Al—Si alloy.

In this embodiment, the first end of the n-type polysilicon wire 61, the first end of the p-type polysilicon wire 62, and the first connector 63 of each of the plurality of thermocouples 60 of each thermopile 6 constitute one hot junction T1. Thus, each thermopile 6 has a plurality of (nine) hot junctions T1. Moreover, the second end of the n-type polysilicon wire 61, the second end of the p-type polysilicon wire 62, and the second connector 64 of each two adjacent thermocouples 60 of each thermopile 6 constitute one cold junction T2. Thus, each thermopile 6 has a plurality of (eight) cold junctions T2.

Each hot junction T1 of the thermopile 6 is disposed to overlap the cavity 13 in the thickness direction D1 of the substrate 1. Each cold junction T2 is disposed so as not to overlap the cavity 13 in the thickness direction D1 of the substrate 1. That is, each hot junction T1 is included in a first portion 41 of the thermal infrared detector 4, the first portion 41 overlapping the cavity 13. Each cold junction T2 is included in a second portion 42 of the thermal infrared detector 4, the second portion 42 not overlapping the cavity 13.

The plurality of cavities 13 is formed by subjecting the substrate 1 to anisotropy etching based on the crystal plane orientation dependency of the speed of etching the silicon substrate. Since the first principal surface 11 of the substrate 1 is the (100) plane, an inner periphery of each cavity 13 has four (111) planes intersecting each other. In this embodiment, an etching solution adopted when the anisotropy etching is performed is, for example, a TMAH solution heated to a predetermined temperature (e.g., 85° C.). The etching solution is not limited to the TMAH solution, but other alkali-based solutions (e.g., a KOH solution) may be used. The depth of each of the plurality of cavities 13 is less than the thickness of the substrate 1. That is, the plurality of cavities 13 do not extend through the substrate 1.

The infrared sensor 100 further includes a plurality of (four) heaters 8 and a thermometer 9.

The plurality of heaters 8 are provided on the first principal surface 11 of the substrate 1. In this embodiment, the plurality of heaters 8 are indirectly provided on the first principal surface 11 of the substrate 1. For example, the plurality of heaters 8 are provided on the silicon nitride film 32 of the film structural component 3, but this should not be construed as limiting. The plurality of heaters 8 may be provided on, for example, the interlayer insulative film 33 or the passivation film 34.

Each of the plurality of heaters 8 has a meandering shape, more specifically, a square wave shape, in plan view in the thickness direction D1 of the substrate 1, but this should not be construed as limiting. Each heater 8 may have, for example, a triangular-wave shape. In the infrared sensor 100, the plurality of heaters 8 have first ends electrically connected to different pads 801, and the other ends of the plurality of heaters 8 are electrically connected to different pads 802.

The material for each of the plurality of heaters 8 is, for example, metal, but this should not be construed as limiting, and the material may be, for example, an alloy or a polysilicon including an impurity. The polysilicon including the impurity is a polysilicon doped with the impurity and is, for example, an n-type polysilicon or a p-type polysilicon. The impurity concentration of the n-type polysilicon may be the same as or different from the impurity concentration of the n-type polysilicon wire 61 of the thermopile 6. Moreover, the impurity concentration of the p-type polysilicon may be the same as different from the impurity concentration of the p-type polysilicon wire 62 of the thermopile 6.

Each of the plurality of heaters 8 faces another heater 8 of the plurality of heaters 8 via a region 10 including the plurality of thermal infrared detectors 4 in plan view in the thickness direction D1 of the substrate 1.

The four heaters 8 surround the region 10 in plan view in the thickness direction D1 of the substrate 1. In this embodiment, the four heaters 8 are arranged one by one along four sides 14 of the substrate in plan view in the thickness direction D1 of the substrate 1.

The thermometer 9 is provided on the first principal surface 11 of the substrate 1 and is configured to detect the temperature of the substrate 1. In this embodiment, the thermometer 9 is indirectly provided on the first principal surface 11 of the substrate 1. For example, the thermometer 9 is provided on the silicon nitride film 32 of the film structural component 3, but this should not be construed as limiting. The thermometer 9 may be provided on, for example, the interlayer insulative film 33 or the passivation film 34. Moreover, the thermometer 9 may be directly provided on the first principal surface 11 of the substrate 1. The thermometer 9 is, for example, a thin film thermistor element but is not limited to this example.

The infrared sensor 100 includes a plurality of (four) thermometers 9. The plurality of thermometers 9 are arranged to correspond to the plurality of heaters 8 on a one-to-one basis. In this embodiment, each of the plurality of thermometers 9 are arranged in the vicinity of a corresponding one heater 8 of the plurality of heaters 8.

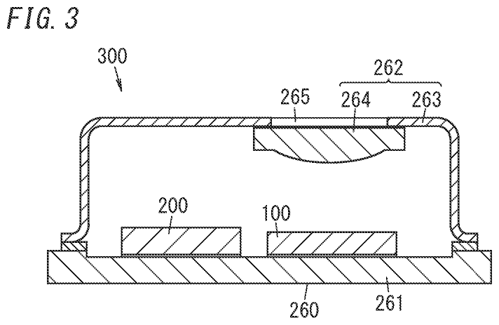

Next, an infrared sensor device 300 including the infrared sensor 100 will be described with reference to FIG. 3.

The infrared sensor device 300 includes the infrared sensor 100 and a signal processing device 200 configured to perform signal processing of an output signal from the infrared sensor 100. The signal processing device 200 is, for example, an IC chip.

The infrared sensor device 300 further includes a package 260. The package 260 accommodates the infrared sensor 100 and the signal processing device 200 therein.

The package 260 has a package body 261 and a package lid 262.

The infrared sensor 100 and the signal processing device 200 are mounted on the package body 261. The package body 261 is a ceramic substrate and is provided with a conductor and the like, for wiring.

The package lid 262 has a box shape and has one surface which is open and which faces the package body 261. The package lid 262 includes a cap 263 and a lens 264. The material for the cap 263 is, for example, metal. The cap 263 is bonded to the package body 261. The cap 263 has a through hole 265 formed in a region overlapping the infrared sensor 100 in the thickness direction D1 of the substrate 1 of the infrared sensor 100. The lens 264 closes the through hole 265 formed in the cap 263. The material for the lens 264 is, for example, silicon. The lens 264 is bonded to the cap 263. A bonding material that bonds the lens 264 to the cap 263 is a conductive material. The lens 264 is, for example, an aspheric lens.

In the infrared sensor device 300 according to a first embodiment, the atmosphere in an internal space of the package 260 is a dry nitrogen atmosphere.

The signal processing device 200 includes a first amplifier circuit, a second amplifier circuit, a first multiplexer, a second multiplexer, a first A/D conversion circuit, a second A/D conversion circuit, a calculator, a memory, and a control circuit.

The first amplifier circuit is configured to amplify an output voltage from the infrared sensor 100. The second amplifier circuit is configured to amplify output voltages from the thermometers 9. The first multiplexer is configured to alternatively input, to the first amplifier circuit, the output voltages from the thermoelectric converters 5 of the plurality of detectors 2 of the infrared sensor 100. The second multiplexer is configured to alternatively input, to the second amplifier circuit, the output voltages from the plurality of the thermometers 9 of the infrared sensor 100. The first A/D conversion circuit is configured to convert the output voltage, which has been output from the infrared sensor 100 and amplified by the first amplifier circuit, into a digital value. The second A/D conversion circuit is configured to convert the output voltage, which has been output from the thermometer 9 and amplified by the second amplifier circuit, into a digital value.

The control circuit is configured to control the plurality of MOS transistors 7 of the infrared sensor 100. Moreover, the control circuit is configured to control the plurality of heaters 8 such that the output voltages of the plurality of thermometers 9 are equal to each other.

The calculator is configured to calculate the temperature of an object in a sensing area of the infrared sensor device 300 by a prescribed calculation formula based on the digital value output from the first A/D conversion circuit in association with the output voltage of the infrared sensor 100 and the digital value output from the second A/D conversion circuit in association with the output voltage of the thermometer 9. In this embodiment, the calculation formula is, for example, a mathematical formula described below, where the temperature of an object is denoted by To, the output voltage of the infrared sensor 100 is denoted by Vout, the temperature (average value of output voltages of the plurality of thermometers 9) of the infrared sensor 100 is denoted by Ts.

$$T o = \frac{- B + \sqrt{{B}^{2} - 4 \cdot A \cdot ( - D \cdot {Ts}^{2} - E \cdot Ts - F + Vout )}}{2 \cdot A} \\ ( where A , B , D , E , and F are coefficients ) \qquad [ Formula 1 ]$$

The memory is configured to store data and the like to be used for the calculation by the calculator.

Note that the infrared sensor device 300 includes a chip-type thermistor located on the package body 261 and closer to the infrared sensor 100 than to the signal processing device 200, and the calculator may calculate the temperature of the object based on the output voltage of the infrared sensor 100 and an output voltage of the chip-type thermistor.

The sensing area of the infrared sensor device 300 depends on the shape and the like of the lens 264 disposed at the side of a light receiving surface of the infrared sensor 100. The light receiving surface of the infrared sensor 100 is a surface on which infrared rays is incident from the outside of the infrared sensor 100, and the light receiving surface is, for example, a surface on an opposite side of the film structural component 3 from the substrate 1.

In the infrared sensor 100 according to the first embodiment, the thermometer 9 is provided on the first principal surface 11 of the substrate 1 and is configured to detect the temperature of the substrate 1. Moreover, in the infrared sensor 100 according to the first embodiment, each of the plurality of heaters 8 faces another heater 8 of the plurality of heaters 8 via the region 10 including the plurality of thermal infrared detectors 4 in plan view in the thickness direction D1 of the substrate 1. Thus, in the infrared sensor 100 and the infrared sensor device 300 according to a first embodiment, variations in temperature of the cold junctions T2 of each thermal infrared detector 4 can be reduced. In this embodiment, in the infrared sensor 100 and the infrared sensor device 300, the control circuit of the signal processing device 200 controls, based on the output voltages of the plurality of thermometers 9, currents to be caused to flow through the plurality of heaters 8, and thereby, the temperature is uniformly distributed in the substrate 1, and the variations in temperature of the cold junctions T2 of each thermal infrared detector 4 can be reduced.

(First Variation of First Embodiment)

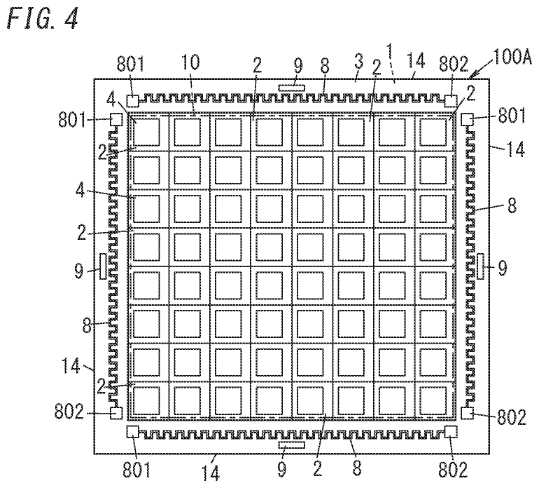

An infrared sensor 100A according to a first variation of the first embodiment will be described with reference to FIG. 4. In the infrared sensor 100A according to the first variation, components similar to those of the infrared sensor 100 according to the first embodiment are denoted by the same reference signs as those in the first embodiment, and the description thereof is omitted.

In the infrared sensor 100 according to the first embodiment, each heater 8 is disposed to face some (in the example shown in the figure, four) thermal infrared detectors 4 of the eight thermal infrared detector 4 aligned in the column direction or the row direction. In contrast, the infrared sensor 100A according to the first variation includes each heater 8 disposed to face eight thermal infrared detector 4 aligned in the column direction or the row direction. Thus, in the infrared sensor 100A according to the first variation, variations in temperature of cold junctions T2 of each thermal infrared detector 4 can be further reduced.

(Second Variation of First Embodiment)

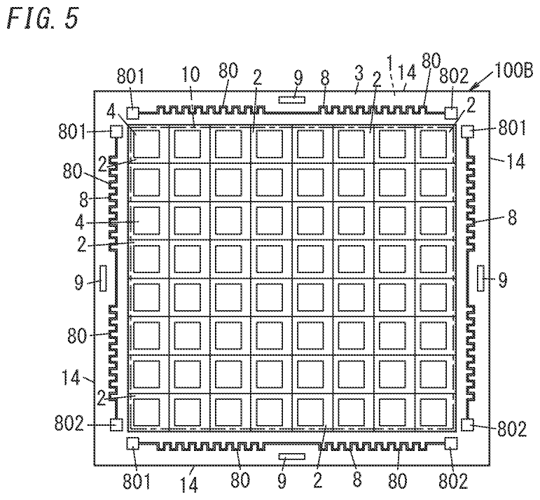

An infrared sensor 100B according to a second variation of the first embodiment will be described with reference to FIG. 5. In the infrared sensor 100B according to the second variation, components similar to those of the infrared sensor 100 according to the first embodiment are denoted by the same reference signs as those in the first embodiment, and the description thereof is omitted.

The infrared sensor 100B according to the second variation includes a plurality of heaters 8 each having two heater elements 80 connected in series to each other. The two heater elements 80 are aligned in a direction along one side 14 of the substrate 1. Thus, in the infrared sensor 100B according to the second variation, variations in temperature of cold junctions T2 of each thermal infrared detector 4 can be further reduced.

### Second Embodiment

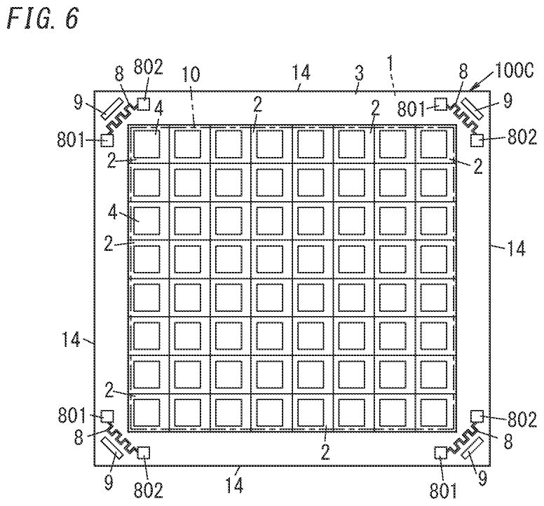

An infrared sensor 100C according to a second embodiment will be described below with reference to FIG. 6. In the infrared sensor 100C according to the second embodiment, components similar to those of the infrared sensor 100 according to a first embodiment are denoted by the same reference signs as those in the first embodiment, and the description thereof is omitted.

The infrared sensor 100C according to the second embodiment includes a plurality of heaters 8 located one by one at four corners of a substrate 1 in plan view in a thickness direction D1 (see FIG. 2) of the substrate 1. Thus, in the infrared sensor 100C according to the second embodiment, each of the plurality of heaters 8 faces another heater 8 of the plurality of heaters 8 via a region 10 including a plurality of thermal infrared detectors 4 in plan view in the thickness direction D1 of the substrate 1. Thus, in the infrared sensor 100C and the infrared sensor device 300 (see FIG. 3) including the infrared sensor 100C in place of the infrared sensor 100 according to the second embodiment, variations in temperature of cold junctions T2 of each thermal infrared detector 4 can be reduced. Moreover, in the infrared sensor 100C, the degree of freedom of disposition of the first pads, the second pads, the third pads, and the fourth pads described in the first embodiment is increased.

### Third Embodiment

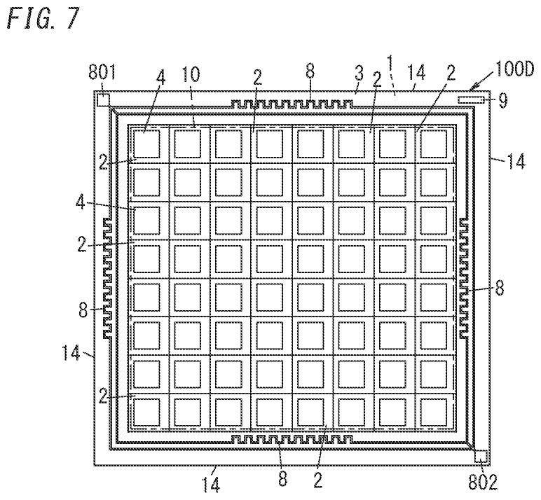

An infrared sensor 100D according to a third embodiment will be described below with reference to FIG. 7. In the infrared sensor 100D according to the third embodiment, components similar to those of the infrared sensor 100 according to the first embodiment are denoted by the same reference signs as those in the first embodiment, and the description thereof is omitted.

The infrared sensor 100D according to the third embodiment includes a plurality of (four) heaters 8 connected in parallel to each other. In the infrared sensor 100D, first ends of the four heaters 8 are commonly connected to one pad 801, and second ends of the four heaters 8 are commonly connected to one pad 802.

In the infrared sensor 100D, the material for each of the plurality of heaters 8 is, for example, a polysilicon including an impurity. Therefore, in the infrared sensor 100D, the value of the Temperature Coefficient of Resistance (TCR) of each of the plurality of heaters 8 is greater than the value of the TCR in the case where the material for each of the plurality of heaters 8 is metal. Thus, in the infrared sensor 100D, a change in resistance value of each of the plurality of heaters 8 due to a temperature change becomes great. Accordingly, if in the infrared sensor 100D, the four heaters 8 vary in temperature, the resistance values of the heaters 8 also vary, and in this case, a heater 8 having a smaller resistance value allows a larger current to flow therethrough and is thus more likely to be increased in temperature. Therefore, in the infrared sensor 100D, variations in temperature of cold junctions T2 of each thermal infrared detector 4 can be further reduced. In the infrared sensor device 300 including the infrared sensor 100D in place of the infrared sensor 100, the control circuit of the signal processing device 200 controls, based on the output voltages of the plurality of thermometers 9, currents to be caused to flow through the plurality of heaters 8, and thereby, the temperature is uniformly distributed in the substrate 1, and the variations in temperature of the cold junctions T2 of each thermal infrared detector 4 can be reduced.

### Fourth Embodiment

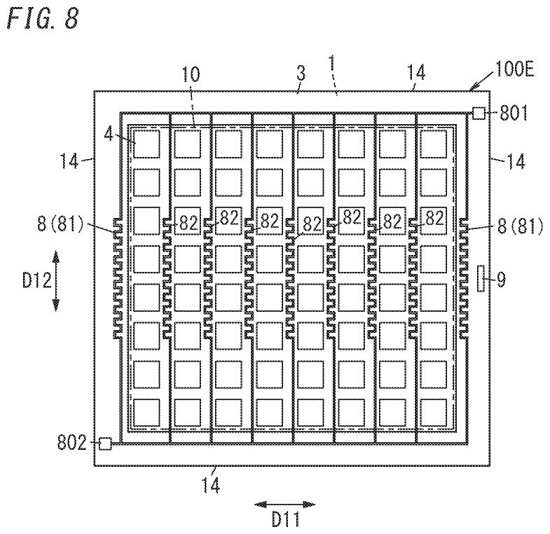

An infrared sensor 100E according to a fourth embodiment will be described below with reference to FIG. 8. In the infrared sensor 100E according to the fourth embodiment, components similar to those of the infrared sensor 100 according to the first embodiment are denoted by the same reference signs as those in the first embodiment, and the description thereof is omitted.

The infrared sensor 100E according to the fourth embodiment further includes a plurality of second heaters 82 in addition to two first heaters 81 as a plurality of heaters 8.

A plurality of thermal infrared detectors 4 include a plurality of groups of thermal infrared detectors 4 aligned, in plan view in a thickness direction D1 (see FIG. 2) of a substrate 1, in a second direction D12 orthogonal to a first direction D11 in which the two first heaters 81 are aligned. The plurality of second heaters 82 are located between the groups of the thermal infrared detectors 4 adjacent to each other in the first direction D11 in plan view in the thickness direction D1 of the substrate 1, and the second heaters 82 are apart from each other in the first direction D11.

In the infrared sensor 100E, the two first heaters 81 and the plurality of second heaters 82 are connected in parallel to each other.

In the infrared sensor 100E, the material for each of the two first heaters 81 and the plurality of second heaters 82 is a polysilicon including an impurity.

In the infrared sensor 100E, the TCR of each of the two first heaters 81 and the plurality of second heaters 82 is larger than in the case where the material for each of the two first heaters 81 and the plurality of second heaters 82 is metal. Accordingly, in the infrared sensor 100E, if the two first heaters 81 and the plurality of second heaters 82 vary in temperature, the resistance values also vary, and in this case, the smaller the resistance value is, the larger a current flows, and the temperature is thus more likely to be increased. Thus, in the infrared sensor 100E, variations in temperature of the two first heaters 81 and the plurality of second heaters 82 are reduced, and variations in temperature of cold junctions T2 of each thermal infrared detector 4 can be reduced.

(Other Variations)

The embodiments are mere examples of various embodiments of the present disclosure. Various modifications may be made to the embodiments depending on design and the like as long as the object of the present invention is achieved.

For example, the number and the arrangement of the plurality of detectors 2 are not limited to the examples described above. For example, the plurality of detectors 2 are at least arranged in an array, but the array is not limited to the two-dimensional array. The detectors 2 may be arranged in one-dimensional array or in a honeycomb array.

Moreover, a connection relationship of the plurality of thermopiles 6 in each thermoelectric converter 5 is not limited to the examples described above. That is, each thermoelectric converter 5 is not limited to have a configuration in which all of the plurality of thermopiles 6 are connected in series to each other. The plurality of thermopiles 6 may be connected in parallel to each other, or the plurality of thermopiles 6 may be connected in series-parallel to each other. Moreover, each thermoelectric converter 5 does not have to include the plurality of thermopiles 6 but may include, for example, one thermopile 6.

The plurality of heaters 8 do not have to be indirectly provided on the first principal surface 11 of the substrate 1, but the heaters 8 may be directly provided on the first principal surface 11 of the substrate 1.

Moreover, the substrate 1 is not limited to the silicon substrate but may be, for example, a Silicon on Insulator (SOI) substrate, a metal substrate, or the like.

Moreover, the plurality of heaters 8 are not limited to the four heaters 8 but may be, for example, two heaters 8.

Moreover, in the infrared sensor 100, each of the detectors 2 includes the MOS transistor 7, but this should not be construed as limiting. The MOS transistors 7 may be provided to respective components other than the detectors 2. Moreover, each MOS transistor 7 is not an essential component of the infrared sensor 100.

Moreover, in the infrared sensor device 300, the atmosphere in the internal space of the package 260 may be a vacuum atmosphere.

The signal processing device 200 is not limited to have a configuration in which the signal processing device 200 is constituted by one electronic component, but the signal processing device 200 may include a plurality of electronic components.

(Aspects)

The embodiments and the like described above disclose the following aspects.

An infrared sensor (100; 100A; 100B; 100C; 100D; 100E) of a first aspect includes a substrate (1) and a film structural component (3). The substrate (1) has a first principal surface (11) and a second principal surface (12) located on an opposite side of the first principal surface (11) in a thickness direction (D1) of the substrate (1). The film structural component (3) is supported by the substrate (1) at a side of the first principal surface (11) of the substrate (1). The film structural component (3) includes a plurality of thermal infrared detectors (4) arranged in an array. Each of the plurality of thermal infrared detectors (4) includes a thermopile (6) having a plurality of hot junctions (T1) and a plurality of cold junctions (T2). The infrared sensor (100; 100A; 100B; 100C; 100D; 100E) further includes a plurality of heaters (8) and at least one thermometer (9). The plurality of heaters (8) are provided on the first principal surface (11) of the substrate (1). The at least one thermometer (9) is provided on the first principal surface (11) of the substrate (1) and is configured to detect a temperature of the substrate (1). Each of the plurality of heaters (8) faces another heater (8) of the plurality of heaters (8) via a region (10) including the plurality of thermal infrared detectors (4) in plan view in the thickness direction (D1) of the substrate (1).

In the infrared sensor (100; 100A; 100B; 100C; 100D; 100E) of the first aspect, variations in temperature of the cold junctions (T2) of each thermal infrared detector (4) can be reduced.

In an infrared sensor (100; 100A; 100B; 100C; 100D; 100E) of a second aspect referring to the first aspect, the substrate (1) has a plurality of cavities (13) at the side of the first principal surface (11). The plurality of cavities (13) corresponds to the plurality of thermal infrared detectors (4) on a one-to-one basis. In each of the plurality of thermal infrared detectors (4), the plurality of hot junctions (T1) are arranged such that the plurality of hot junctions (T1) overlap a corresponding cavity (13) of the plurality of cavities (13). In each of the plurality of thermal infrared detectors (4), the plurality of cold junctions (T2) are arranged such that the plurality of cold junctions (T2) do not overlap the corresponding cavity (13) of the plurality of cavities (13).

In the infrared sensor (100; 100A; 100B; 100C; 100D; 100E) of the second aspect, a thermal capacity between each of the plurality of thermal infrared detectors (4) and the substrate (1) is further increased, and variations in temperature of the cold junctions (T2) of each of the thermal infrared detectors (4) are further reduced.

In an infrared sensor (100; 100A; 100B; 100C; 100D) according to a third aspect referring to the first or second aspect, the plurality of heaters (8) surround the region (10) in plan view in the thickness direction (D1) of the substrate (1). In the infrared sensor (100; 100A; 100B; 100C; 100D) of the third aspect, the at least one thermometer (9) includes a plurality of thermometers (9). The plurality of thermometers (9) are arranged in association with the plurality of heaters (8) on a one-to-one basis.

In the infrared sensor (100; 100A; 100B; 100C; 100D) of the third aspect, the plurality of thermometers (9) arranged in association with the plurality of heaters (8) on a one-to-one basis measure the temperature of the substrate (1).

In an infrared sensor (100; 100A; 100B; 100C; 100D) according to a fourth aspect referring to the third aspect, the plurality of heaters (8) include only four heaters (8).

In the infrared sensor (100; 100A; 100B; 100C; 100D) of the fourth aspect, variations in temperature of the cold junctions (T2) of each of the thermal infrared detectors (4) are further reduced as compared to the case where only two heaters (8) are provided as the plurality of heaters (8).

In an infrared sensor (100; 100A; 100B; 100D) according to a fifth aspect referring to the first or second aspect, the plurality of heaters (8) surround the region (10) in plan view in the thickness direction of the substrate (1). the plurality of heaters (8) include only four heaters (8). The plurality of heaters (8) are arranged one by one along four sides (14) of the substrate (1) in plan view in the thickness direction (D1) of the substrate (1).

In the infrared sensor (100; 100A; 100B; 100D) of the fifth aspect, variations in temperature of the cold junctions (T2) of each of the thermal infrared detectors (4) are further reduced as compared to the case where only two heaters (8) are provided as the plurality of heaters (8).

In an infrared sensor (100D) according to a sixth aspect referring to the fifth aspect, the plurality of heaters (8) are connected in parallel.

In the infrared sensor (100D) of the sixth aspect, the number of pads (801) and (802) via which currents are caused to flow through the plurality of heaters (8) is reduced.

In an infrared sensor (100D) according to a seventh aspect referring to the sixth aspect, a material for each of the plurality of heaters (8) is a polysilicon including an impurity.

In the infrared sensor (100D) of the seventh aspect, variations in temperature of the cold junctions (T2) of each of the thermal infrared detectors (4) are further reduced.

In an infrared sensor (100C) according to an eighth aspect referring to the third aspect, the plurality of heaters (8) are located one by one at four corners of the substrate (1) in plan view in the thickness direction (D1) of the substrate (1).

In the infrared sensor (100C) of the eighth aspect, variations in temperature of the cold junctions (T2) of each of the thermal infrared detectors (4) are further reduced as compared to the case where only two heaters (8) are provided as the plurality of heaters (8).

An infrared sensor (100E) of a ninth aspect referring to the first or second aspect further includes a plurality of second heaters (82), in addition to two first heaters (81) as the plurality of heaters (8). The plurality of thermal infrared detectors (4) are aligned in a two-dimensional array. The plurality of thermal infrared detectors (4) include a plurality of groups of thermal infrared detectors (4) aligned, in plan view in the thickness direction (D1) of the substrate (1), in a second direction (D12) orthogonal to a first direction (D11) in which the two first heaters (81) are aligned. In plan view in the thickness direction (D1) of the substrate (1), the plurality of second heaters (82) are located between the groups of the thermal infrared detectors (4) adjacent to each other in the first direction (D11), and the second heaters (82) are apart from each other in the first direction (D11).

In the infrared sensor (100E) of the ninth aspect, variations in temperature of the cold junctions (T2) of each of the thermal infrared detectors (4) are further reduced as compared to the case where only two first heaters (81) are provided as the plurality of heaters (8).

In an infrared sensor (100E) according to a tenth aspect referring to the ninth aspect, the two first heaters (81) and the plurality of second heaters (82) are connected in parallel to each other.

In the infrared sensor (100E) of the tenth aspect, the number of pads (801) and (802) via which currents are caused to flow through the two first heaters (81) and the plurality of second heaters (82) is reduced.

In an infrared sensor (100E) according to an eleventh aspect referring to the tenth aspect, a material for each of the two first heaters (81) and the plurality of second heaters (82) is a polysilicon including an impurity.

In the infrared sensor (100E) of the eleventh aspect, the TCR of each of the two first heaters (81) and the plurality of second heaters (82) is greater than in the case where the material for each of the two first heaters (81) and the plurality of second heaters (82) is metal. Accordingly, in the infrared sensor (100E) of the eleventh aspect, if the two first heaters (81) and the plurality of second heaters (82) vary in temperature, the resistance values also vary, and in this case, the smaller the resistance value is, the larger a current flows, and the temperature is thus more likely to be increased. In the infrared sensor (100E) of the eleventh aspect, variations in temperature of the two first heaters (81) and the plurality of second heaters (82) are reduced, and variations in temperature of the cold junctions (T2) of each thermal infrared detector (4) can be more reduced.

In an infrared sensor (100; 100A; 100B; 100C; 100D; 100E) according to a twelfth aspect referring to any one of the first to eleventh aspects, the substrate (1) is a silicon substrate.

An infrared sensor device (300) of a thirteenth aspect includes the infrared sensor (100; 100A; 100B; 100C; 100D; 100E) of any one of the first to twelfth aspect; and a signal processing device (200) configured to perform signal processing of an output signal from the infrared sensor (100; 100A; 100B; 100C; 100D; 100E).

In the infrared sensor device (300) of the thirteenth aspect, variations in temperature of the cold junctions (T2) of each thermal infrared detector (4) is reduced.

The configurations according to the second to twelfth aspects are not essential configurations of the infrared sensor device (300) and may accordingly be omitted.

### REFERENCE SIGNS LIST

1 Substrate
11 First Principal Surface
12 Second Principal Surface
13 Cavity
14 Side
3 Film Structural Component
4 Thermal Infrared Detector
6 Thermopile
8 Heater
81 First Heater
82 Second Heater
9 Thermometer
100, 100A, 100B, 100C, 100D, 100E Infrared Sensor
200 Signal Processing Device
300 Infrared Sensor Device
D1 Thickness Direction
D11 First Direction
D12 Second Direction
T1 Hot Junction
T2 Cold Junction

1. An infrared sensor, comprising:
a substrate having a first principal surface and a second principal surface located on an opposite side of the first principal surface in a thickness direction of the substrate; and
a film structural component supported by the substrate at a side of the first principal surface of the substrate,
the film structural component including a plurality of thermal infrared detectors arranged in an array, each of the plurality of thermal infrared detectors including a thermopile having a plurality of hot junctions and a plurality of cold junctions,
the infrared sensor further including
a plurality of heaters provided on the first principal surface of the substrate and
at least one thermometer provided on the first principal surface of the substrate and being configured to detect a temperature of the substrate,
each of the plurality of heaters facing another heater of the plurality of heaters via a region including the plurality of thermal infrared detectors in plan view in the thickness direction of the substrate.

2. The infrared sensor of claim 1, wherein
the substrate has a plurality of cavities at the side of the first principal surface, the plurality of cavities corresponding to the plurality of thermal infrared detectors on a one-to-one basis,
in each of the plurality of thermal infrared detectors, the plurality of hot junctions are arranged such that the plurality of hot junctions overlap a corresponding cavity of the plurality of cavities, and
in each of the plurality of thermal infrared detectors, the plurality of cold junctions are arranged such that the plurality of cold junctions do not overlap the corresponding cavity of the plurality of cavities.

3. The infrared sensor of claim 1, wherein
the plurality of heaters surround the region in plan view in the thickness direction of the substrate,
the at least one thermometer includes a plurality of thermometers, and
the plurality of thermometers are arranged in association with the plurality of heaters on a one-to-one basis.

4. The infrared sensor of claim 3, wherein
the plurality of heaters include only four heaters.

5. The infrared sensor of claim 1, wherein
the plurality of heaters surround the region in plan view in the thickness direction of the substrate,
the plurality of heaters include only four heaters, and
the plurality of heaters are arranged one by one along four sides of the substrate in plan view in the thickness direction of the substrate.

6. The infrared sensor of claim 5, wherein
the plurality of heaters are connected in parallel.

7. The infrared sensor of claim 6, wherein
a material for each of the plurality of heaters is a polysilicon including an impurity.

8. The infrared sensor of claim 3, wherein
the plurality of heaters are located one by one at four corners of the substrate in plan view in the thickness direction of the substrate.

9. The infrared sensor of claim 1, further comprising a plurality of second heaters. in addition to two first heaters as the plurality of heaters, wherein
the plurality of thermal infrared detectors are aligned in a two-dimensional array,
the plurality of thermal infrared detectors include a plurality of groups of thermal infrared detectors aligned, in plan view in the thickness direction of the substrate, in a second direction orthogonal to a first direction in which the two first heaters are aligned, and
in plan view in the thickness direction of the substrate, the plurality of second heaters are located between the groups of the thermal infrared detectors adjacent to each other in the first direction, and the second heaters are apart from each other in the first direction.

10. The infrared sensor of claim 9, wherein
the two first heaters and the plurality of second heaters are connected in parallel to each other.

11. The infrared sensor of claim 10, wherein
a material for each of the two first heaters and the plurality of second heaters is a polysilicon including an impurity.

12. The infrared sensor of claim 1, wherein
the substrate is a silicon substrate.

13. An infrared sensor device, comprising:
the infrared sensor of claim 1; and
a signal processing device configured to perform signal processing of an output signal from the infrared sensor.
